(19) United States
(12) Patent Application Publication
(10) Pub. No.: US 2024/0221804 A1
(43) Pub. Date: Jul. 4, 2024

(54) DYNAMIC PROGRAMMING TIME FOR A MEMORY DEVICE

(71) Applicant: Micron Technology, Inc., Boise, ID (US)

(72) Inventors: Yue WANG, Beijing City (CN); Jingcheng YUAN, Tokyo (JP)

(21) Appl. No.: 18/538,652

(22) Filed: Dec. 13, 2023

(30) Foreign Application Priority Data
Dec. 29, 2022 (CN) 202211708950.0

(51) Int. Cl. G11C 7/10; G11C 7/20; G11C 7/22

(52) U.S. Cl. CPC G11C 7/1096; G11C 7/20; G11C 7/222

(57) ABSTRACT

In some implementations, a memory device may receive a write command indicating data to be programmed. The memory device may determine a programming time, from a first programming time and a second programming time, to be used to program the data, wherein the programming time indicates an amount of time to be associated with programming the data, and wherein the first programming time is associated with a first amount of time and the second programming time is associated with a second amount of time. The memory device may program the data to a memory of the memory device using the programming time.

### CROSS-REFERENCE TO RELATED APPLICATION

This Patent application claims priority to China Patent Application No. 202211708950.0, filed on Dec. 29, 2022, entitled “DYNAMIC PROGRAMMING TIME FOR A MEMORY DEVICE,” and assigned to the assignee hereof. The disclosure of the prior Application is considered part of and is incorporated by reference into this Patent Application.

### TECHNICAL FIELD

The present disclosure generally relates to memory devices, memory device operations, and, for example, to a dynamic programming time for a memory device.

### BACKGROUND

A non-volatile memory device, such as a NAND memory device, may use circuitry to enable electrically programming, erasing, and storing of data even when a power source is not supplied. Non-volatile memory devices may be used in various types of electronic devices, such as computers, mobile phones, or automobile computing systems, among other examples.

A non-volatile memory device may include an array of memory cells, a page buffer, and a column decoder. In addition, the non-volatile memory device may include a control logic unit (e.g., a controller), a row decoder, or an address buffer, among other examples. The memory cell array may include memory cell strings connected to bit lines, which are extended in a column direction.

A memory cell, which may be referred to as a “cell” or a “data cell,” of a non-volatile memory device may include a current path formed between a source and a drain on a semiconductor substrate. The memory cell may further include a floating gate and a control gate formed between insulating layers on the semiconductor substrate. A programming operation (sometimes called a write operation) of the memory cell is generally accomplished by grounding the source and the drain areas of the memory cell and the semiconductor substrate of a bulk area, and applying a high positive voltage, which may be referred to as a “program voltage,” a “programming power voltage,” or “VPP,” to a control gate to generate Fowler-Nordheim tunneling (referred to as “F-N tunneling”) between a floating gate and the semiconductor substrate. When F-N tunneling is occurring, electrons of the bulk area are accumulated on the floating gate by an electric field of VPP applied to the control gate to increase a threshold voltage of the memory cell.

An erasing operation of the memory cell is concurrently performed in units of sectors sharing the bulk area (referred to as “blocks”), by applying a high negative voltage, which may be referred to as an “erase voltage” or “Vera,” to the control gate and a configured voltage to the bulk area to generate the F-N tunneling. In this case, electrons accumulated on the floating gate are discharged into the source area, so that the memory cells have an erasing threshold voltage distribution.

Each memory cell string may have a plurality of floating gate type memory cells serially connected to each other. Access lines (sometimes called “word lines”) are extended in a row direction, and a control gate of each memory cell is connected to a corresponding access line. A non-volatile memory device may include a plurality of page buffers connected between the bit lines and the column decoder. The column decoder is connected between the page buffer and data lines.

### BRIEF DESCRIPTION OF THE DRAWINGS

FIG. 1 is a diagram illustrating an example system capable of using a dynamic programming time for a memory device.

FIG. 2 is a diagram of example components included in a memory device.

FIG. 3 is a diagram illustrating an example of single-level cell (SLC), multi-level cell (MLC), triple-level cell (TLC), and quad-level cell (QLC) non-volatile memory.

FIG. 4 is a diagram illustrating an example of read errors that may occur in an MLC non-volatile memory device.

FIGS. 5A and 5B are diagrams of an example of dynamic programming time for a memory device.

FIG. 6 is a diagram of an example of a timeline associated with a dynamic programming time for a memory device.

FIG. 7 is a diagram of an example of a dynamic programming time for a memory device.

FIG. 8 is a diagram of an example of dynamic programming time for a memory device.

FIG. 9 is a flowchart of an example method associated with a dynamic programming time for a memory device.

FIG. 10 is a flowchart of an example method associated with a dynamic programming time for the memory device.

FIG. 11 is a flowchart of an example method associated with a dynamic programming time for the memory device.

### DETAILED DESCRIPTION

Non-volatile memory cells can be programmed to a desired state, such as to one of multiple states. In some cases, a non-volatile memory device, such as a NAND device, may store bits of data by charging or not charging memory cells, which may be capable of retaining a charge (e.g., electrons) even when no voltage is applied to the cell. For example, a non-volatile, solid-state memory device (e.g., a flash memory device) may include a floating gate transistor configured to store electrical charge. A lack of charge in the floating gate transistor, a presence of a charge in the floating gate transistor, and/or a level of the charge in the floating gate transistor indicates a data state stored by the memory cell or floating gate transistor. A memory cell programmed as a single level cell (SLC) can store one of two binary states (e.g., 1 or 0). A memory cell programmed as a multi-level cell (MLC) can store more than two binary states. For example, a quad-level cell (QLC) can be programmed to store one of 16 states, such as 1111, 0111, 0011, 1011, 1001, 0001, 0101, 1101, 1100, 0100, 0000, 1000, 1010, 0010, 0110, and 1110. The states can correspond to different threshold voltage (Vth) distributions that are separated from each other by Vth margins, such as sensing (e.g., read) margins. For example, a state can be sensed (e.g., read) using a sensing voltage that can be selected to lie within a Vth margin.

Data operations may be performed by the non-volatile memory device. For example, the non-volatile memory device may receive access requests (e.g., a write command or a read command), such as to store data on a memory at the non-volatile memory device and/or to read data from the memory on the non-volatile memory device. The memory device may retain the stored data over time (e.g., over a life span of the memory device).

However, data retention degradation (e.g., a reduction of cell capacitance to retain stored data) can impact the reliability and/or the functionality of non-volatile memory devices. Data retention degradation may be associated with extended periods of storage (e.g., unpowered storage). For example, based on temperatures experienced by the non-volatile memory device and/or an amount of time associated with unpowered storage, a level of charge of a cell may fluctuate. The fluctuation of the level of charge may result in the level of charge changing from one binary state to another binary state over time. For example, a cell may be charged to correspond to a first voltage distribution associated with a first binary state, but over time the level of charge may change to a second voltage distribution associated with a second binary state. This may result in errors associated with reading the data stored by the cell.

In some cases, data retention degradation due to extended periods of storage may negatively impact data integrity. Accordingly, failure to mitigate data retention degradation may result in negative impacts to the reliability and/or the functionality of non-volatile memory devices. The issues associated with data retention may depend on the Vth margins described above and/or drifting of Vth distributions. For example, the integrity of the data can degrade as the Vth margins become smaller. Therefore, as a number of bits per cell increases, data may degrade faster because the Vth margins are smaller. For example, QLC non-volatile memory may be associated with relatively small differences between Vth threshold values for different binary states. As a result, QLC non-volatile memory may experience higher levels of bit errors caused by data retention degradation associated with unpowered storage and/or temperature effects. This may negatively impact data integrity, reliability, and/or the functionality of QLC non-volatile memory devices.

In some cases, a memory device may be capable of performing error corrections, such as by using an error correction code (ECC), among other examples. However, if a number of errors becomes too large, the memory device may experience an uncorrectable ECC (UECC) error and data may be lost. In some cases, data for a QLC non-volatile memory device may be written as an SLC to improve data integrity and/or mitigate the effects of data retention degradation (e.g., because SLC non-volatile memory is associated with larger Vth margins). However, this may reduce a data capacity of the QLC non-volatile memory (e.g., because SLC memory is only capable of storing 1 bit per cell, rather than 4 bits per cell). Additionally, this may negatively impact performance of the QLC non-volatile memory because the data stored in SLC memory may need to be read and re-written (e.g., folded) to QLC memory in the future.

A memory device (e.g., a non-volatile memory device) may write or program data using a programming time. “Programming time” may refer to an amount of time associated with the memory device writing data to a cell or a page. The programming time may also be referred to as a program time, a write time, and/or a tProg, among other examples. In some cases, increasing the programming time may improve data integrity and/or may mitigate the effects of data retention degradation because the memory device is enabled to increase and/or decrease a level of charge of a cell with greater precision (e.g., thereby reducing a likelihood that the level of charge is close to a Vth threshold, which may reduce a likelihood that a fluctuation of the level of charge results in an error). However, increasing the programming time may negatively impact the performance of the memory device since write operations may take more time, thereby increasing a delay or latency associated with performing the write operations.

Some implementations described herein enable a dynamic programming time for a memory device. For example, the memory device may write or program data using a first programming time (e.g., associated with a first amount of time) at a first time and may write or program data using a second programming time (e.g., associated with a second amount of time) at a second time. For example, the memory device may dynamically switch between different programming times for writing or programming data to a memory cell.

For example, the memory device may perform first one or more write operations using a first programming time. The memory device may detect a trigger event associated with changing a programming time used by the memory device. For example, the trigger event may be based on a command received by the memory device (e.g., from a host device), a quantity of times that a memory block has been erased, and/or a quantity of program-erase cycles associated with a memory block, among other examples. The memory device may switch, based on detecting the trigger event, the programming time from the first programming time to a second programming time. The memory device may perform one or more write operations using the second programming time.

In some implementations, the programming time used by the memory device may be based on an operation phase of the memory device. For example, the memory device may be configured to use the first programming time for a manufacturing and/or initialization phase (e.g., associated with an original equipment manufacturer (OEM) or original design manufacturer (ODM) storing data in memory of the memory device). The memory device may be configured to use the second programming time for an end user phase (e.g., associated with use by an end user of the memory device and/or host device associated with the memory device). For example, in a typical case, after the manufacturing and/or initialization phase, the memory device may be shipped and/or stored for long periods of time in an unpowered state. As a result, improving data integrity and/or mitigating the effects of data retention degradation may be important for data written during the manufacturing and/or initialization phase. Therefore, the memory device may be configured to use the first programming time (e.g., a longer programming time) to write or program data during the manufacturing and/or initialization phase. In the end user phase, the memory device may be in a powered state and may be capable of correcting errors in stored data by performing refresh operations, as described in more detail elsewhere herein. Therefore, the memory device may be configured to use the second programming time (e.g., a shorter programming time) to write or program data during the end user phase to improve the performance of the memory device.

As a result, by dynamically changing the programming time used by the memory device, the memory device is enabled to improve data integrity and/or mitigate the effects of data retention degradation by writing data using a longer programming time in some cases while also improving the performance of the memory device by writing data using a shorter programming time in other cases. For example, the memory device is enabled to balance between improving data integrity and performance of the memory device based on an operation phase and/or a type of data being stored by the memory device. This enables the memory device to improve data integrity and/or mitigate the effects of data retention degradation (e.g., associated with periods of unpowered storage and/or transportation) without degrading the performance of the memory device (e.g., for an end user).

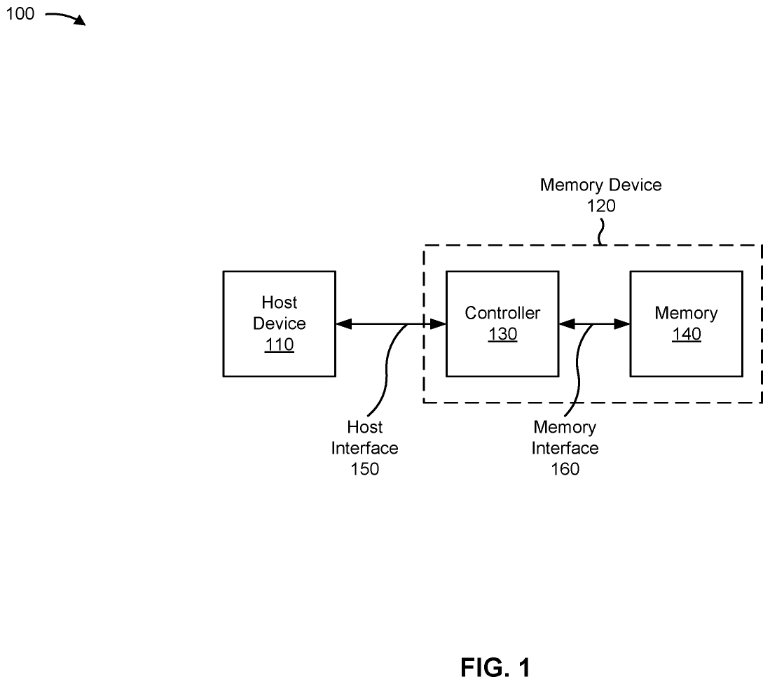

FIG. 1 is a diagram illustrating an example system 100 capable of using a dynamic programming time for a memory device. The system 100 may include one or more devices, apparatuses, and/or components for performing operations described herein. For example, the system 100 may include a host device 110 and a memory device 120. The memory device 120 may include a controller 130 and memory 140. The host device 110 may communicate with the memory device 120 (e.g., the controller 130 of the memory device 120) via a host interface 150. The controller 130 and the memory 140 may communicate via a memory interface 160.

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host device 110 may include one or more processors configured to execute instructions and store data in the memory 140. For example, the host device 110 may include a central processing unit (CPU), a graphics processing unit (GPU), a field-programmable gate array (FPGA), an application-specific integrated circuit (ASIC), and/or another type of processing component.

The memory device 120 may be any electronic device or apparatus configured to store data in memory. In some implementations, the memory device 120 may be an electronic device configured to store data persistently in non-volatile memory. For example, the memory device 120 may be a hard drive, a solid-state drive (SSD), a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device. In this case, the memory 140 may include non-volatile memory configured to maintain stored data after the memory device 120 is powered off. For example, the memory 140 may include NAND memory or NOR memory. In some implementations, the memory 140 may include volatile memory that requires power to maintain stored data and that loses stored data after the memory device 120 is powered off, such as one or more latches and/or random-access memory (RAM), such as dynamic RAM (DRAM) and/or static RAM (SRAM). For example, the volatile memory may cache data read from or to be written to non-volatile memory, and/or may cache instructions to be executed by the controller 130.

The controller 130 may be any device configured to communicate with the host device (e.g., via the host interface 150) and the memory 140 (e.g., via the memory interface 160). Additionally, or alternatively, the controller 130 may be configured to control operations of the memory device 120 and/or the memory 140. For example, the controller 130 may include a memory controller, a system controller, an ASIC, an FPGA, a processor, a microcontroller, and/or one or more processing components. In some implementations, the controller 130 may be a high-level controller, which may communicate directly with the host device 110 and may instruct one or more low-level controllers regarding memory operations to be performed in connection with the memory 140. In some implementations, the controller 130 may be a low-level controller, which may receive instructions regarding memory operations from a high-level controller that interfaces directly with the host device 110. As an example, a high-level controller may be an SSD controller, and a low-level controller may be a non-volatile memory controller (e.g., a NAND controller) or a volatile memory controller (e.g., a DRAM controller). In some implementations, a set of operations described herein as being performed by the controller 130 may be performed by a single controller (e.g., the entire set of operations may be performed by a single high-level controller or a single low-level controller). Alternatively, a set of operations described herein as being performed by the controller 130 may be performed by more than one controller (e.g., a first subset of the operations may be performed by a high-level controller and a second subset of the operations may be performed by a low-level controller).

The host interface 150 enables communication between the host device 110 and the memory device 120. The host interface 150 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, and/or an embedded multimedia card (eMMC) interface.

The memory interface 160 enables communication between the memory device 120 and the memory 140. The memory interface 160 may include a non-volatile memory interface (e.g., for communicating with non-volatile memory), such as a NAND interface or a NOR interface. Additionally, or alternatively, the memory interface 160 may include a volatile memory interface (e.g., for communicating with volatile memory), such as a double data rate (DDR) interface.

In some implementations, the memory device 120 and/or the controller 130 may be configured to perform first one or more write operations using a first programming time, wherein the first programming time is associated with a first amount of time; detect a trigger event associated with changing a programming time used by the memory device; switch, based on detecting the trigger event, the programming time from the first programming time to a second programming time, wherein the second programming time is associated with a second amount of time; and perform second one or more write operations using the second programming time.

In some implementations, the memory device 120 and/or the controller 130 may be configured to receive a write command indicating data to be programmed; determine a programming time, from a first programming time and a second programming time, to be used to program the data, wherein the programming time indicates an amount of time to be associated with programming the data, and wherein the first programming time is associated with a first amount of time and the second programming time is associated with a second amount of time; and program the data to a memory of the memory device using the programming time.

In some implementations, the memory device 120 and/or the controller 130 may be configured to perform a first one or more write operations using a first amount of time for a programming time, wherein the programming time indicates an amount of time associated with performing a write operation from the first one or more write operations; detect a trigger event associated with changing the amount of time associated with the programming time; and perform a second one or more write operations using a second amount of time for the programming time based on detecting the trigger event.

As indicated above, FIG. 1 is provided as an example. Other examples may differ from what is described with regard to FIG. 1.

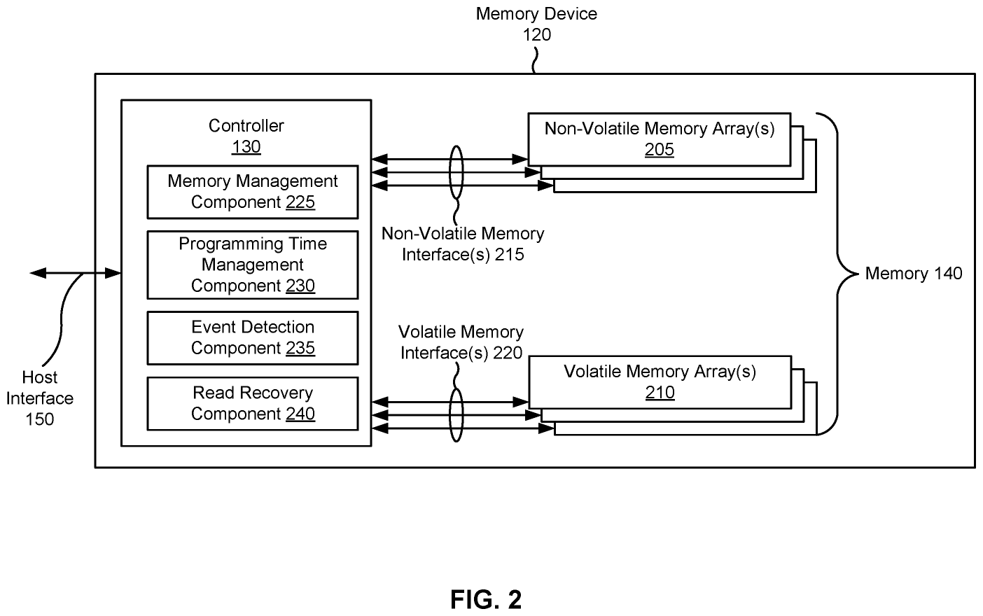

FIG. 2 is a diagram of example components included in a memory device 120. As described above in connection with FIG. 1, the memory device 120 may include a controller 130 and memory 140. As shown in FIG. 2, the memory 140 may include one or more non-volatile memory arrays 205, such as one or more NAND memory arrays and/or one or more NOR memory arrays. Additionally, or alternatively, the memory 140 may include one or more volatile memory arrays 210, such as one or more SRAM arrays and/or one or more DRAM arrays. The controller 130 may transmit signals to and receive signals from a non-volatile memory array 205 using a non-volatile memory interface 215. The controller 130 may transmit signals to and receive signals from a volatile memory array 210 using a volatile memory interface 220.

The controller 130 may control operations of the memory 140, such as by executing one or more instructions. For example, the memory device 120 may store one or more instructions in the memory 140 as firmware, and the controller 130 may execute those one or more instructions. Additionally, or alternatively, the controller 130 may receive one or more instructions from the host device 110 via the host interface 150, and may execute those one or more instructions. In some implementations, a non-transitory computer-readable medium (e.g., volatile memory and/or non-volatile memory) may store a set of instructions (e.g., one or more instructions or code) for execution by the controller 130. The controller 130 may execute the set of instructions to perform one or more operations or methods described herein. In some implementations, execution of the set of instructions, by the controller 130, causes the controller 130 and/or the memory device 120 to perform one or more operations or methods described herein. In some implementations, hardwired circuitry is used instead of or in combination with the one or more instructions to perform one or more operations or methods described herein. Additionally, or alternatively, the controller 130 and/or one or more components of the memory device 120 may be configured to perform one or more operations or methods described herein. An instruction is sometimes called a “command.”

For example, the controller 130 may transmit signals to and/or receive signals from the memory 140 based on the one or more instructions, such as to transfer data to (e.g., write or program), to transfer data from (e.g., read), and/or to erase all or a portion of the memory 140 (e.g., one or more memory cells, pages, sub-blocks, blocks, or planes of the memory 140). Additionally, or alternatively, the controller 130 may be configured to control access to the memory 140 and/or to provide a translation layer between the host device 110 and the memory 140 (e.g., for mapping logical addresses to physical addresses of a memory array). In some implementations, the controller 130 may translate a host interface command (e.g., a command received from the host device 110) into a memory interface command (e.g., a command for performing an operation on a memory array).

As shown in FIG. 2, the controller 130 may include a memory management component 225, a programming time management component 230, an event detection component 235, and/or a read recovery component 240, among other examples. In some implementations, one or more of these components are implemented as one or more instructions (e.g., firmware) executed by the controller 130. Alternatively, one or more of these components may be implemented as dedicated integrated circuits distinct from the controller 130.

The memory management component 225 may be configured to manage performance of the memory device 120. For example, the memory management component 225 may perform wear leveling, bad block management, block retirement, read disturb management, and/or other memory management operations. In some implementations, the memory device 120 may store (e.g., in memory 140) one or more memory management tables. A memory management table may store information that may be used by or updated by the memory management component 225, such as information regarding memory block age, memory block erase count (which may also be referred to as a “block erase count”), and/or error information associated with a memory partition (e.g., a memory cell, a row of memory, a block of memory, or the like).

The programming time management component 230 may be configured to manage a programming time used by the memory device 120 and/or the controller 130 to program or write data to a memory cell. For example, the programming time management component 230 may be configured to store an active (or currently used) programming time. The programming time management component 230 may be configured to switch or change an amount of time associated with the programming time based on a detected trigger event, an operation phase of the memory device 120, and/or a command received by the memory device 120 from the host device 110, among other examples.

The event detection component 235 may be configured to detect one or more trigger events associated with dynamically switching the programming time used by the memory device 120 and/or the controller 130 to program or write data to a memory cell. For example, the event detection component 235 may be configured to detect that a command (e.g., a vendor command or a vendor specific (VS) command) has been received (e.g., from the host device 110) indicating that the programming time is to be changed or switched. Additionally, or alternatively, the event detection component 235 may be configured to detect a trigger event based on detecting that a block erase count satisfies an erase count threshold. Additionally, or alternatively, the event detection component 235 may be configured to detect a trigger event based on detecting that a quantity of program-erase cycles associated with a memory block satisfies a program-erase threshold.

The read recovery component 240 may be configured to perform read recovery processes to recover from read page failure and other read failures. In some implementations, the read recovery component 240 may be configured to perform refresh operations and/or read patrol operation, as described in more detail elsewhere herein. For example, the read recovery component 240 may perform one or more read recovery operations such as adjusting a read reference voltage used to read a memory cell, and/or performing one or more additional error correction algorithms (e.g., ECC) or processes such as redundant array of independent NAND (RAIN) recovery processes, redundant array of independent disks (RAID) recovery processes, second sync byte pattern (SB2) decoding processes, hard or soft low density parity check (LDPC) recovery processes, corrective read (CR) processes, and/or automatic calibration recovery (ACR) processes, among other examples.

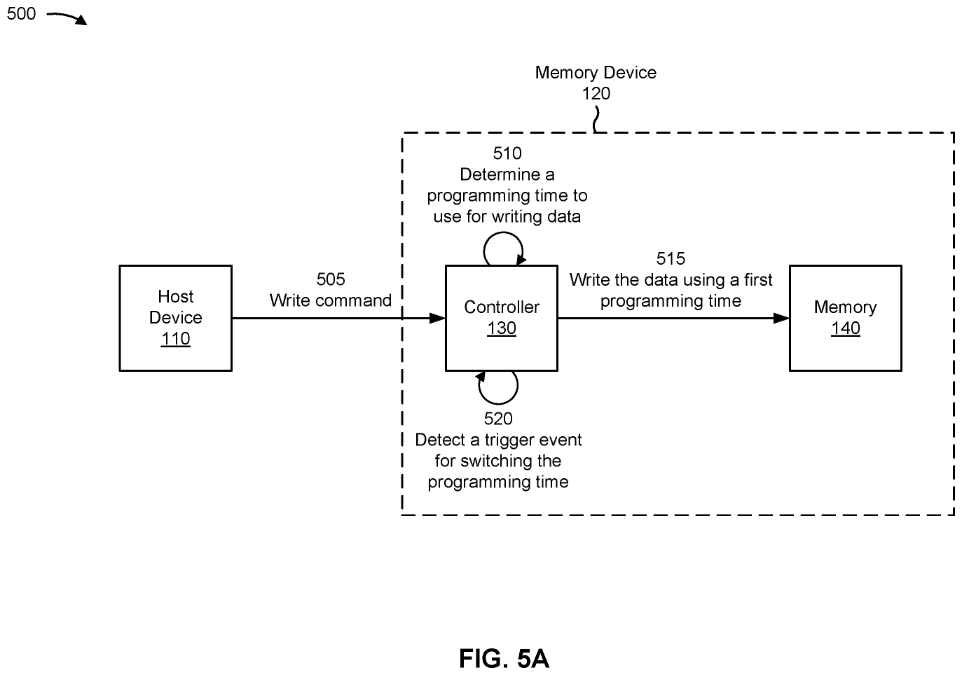

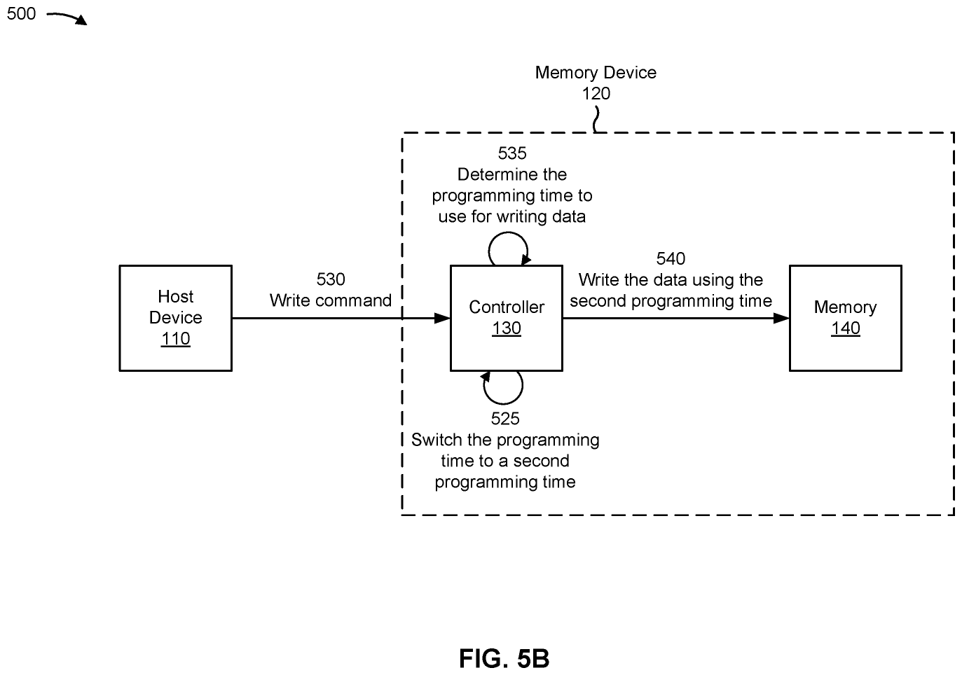

One or more devices or components shown in FIG. 2 may be configured to perform operations described herein, such as one or more operations and/or methods described in connection with FIGS. 5A, 5B, and 6-11. For example, the controller 130, the memory management component 225, the programming time management component 230, the event detection component 235, and/or the read recovery component 240 may be configured to perform one or more operations and/or methods for the memory device 120.

The number and arrangement of components shown in FIG. 2 are provided as an example. In practice, there may be additional components, fewer components, different components, or differently arranged components than those shown in FIG. 2. Furthermore, two or more components shown in FIG. 2 may be implemented within a single component, or a single component shown in FIG. 2 may be implemented as multiple, distributed components. Additionally, or alternatively, a set of components (e.g., one or more components) shown in FIG. 2 may perform one or more operations described as being performed by another set of components shown in FIG. 2.

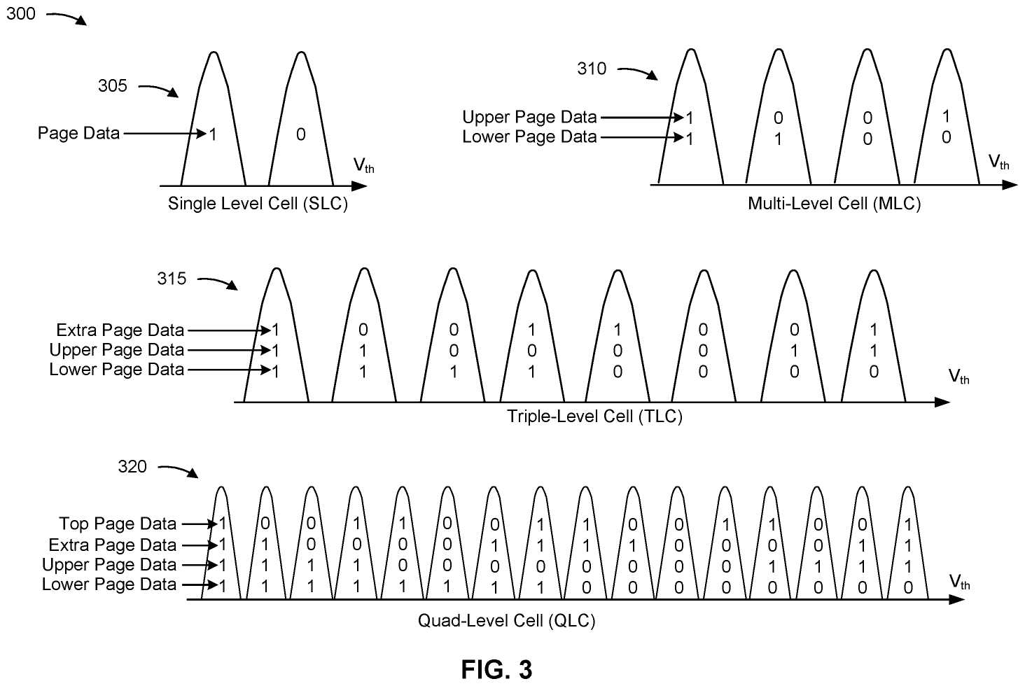

FIG. 3 is a diagram illustrating an example 300 of single-level cell (SLC), multi-level cell (MLC), triple-level cell (TLC), and quad-level cell (QLC) non-volatile memory. One or more of these memory types may be used by the memory device 120 described herein.

In some cases, a non-volatile memory device, such as a NAND device, may store bits of data by charging or not charging memory cells, which may be capable of retaining a charge (e.g., electrons) even when no voltage is applied to the cell. For example, a non-volatile, solid-state memory device (e.g., a flash memory device) may include a floating gate transistor configured to store electrical charge. The floating gate transistor may be isolated above and below by insulating oxide layers. The floating gate transistor may be charged by applying a high voltage to a control gate proximate to a first (or top) insulating layer (sometimes called a gate oxide), which causes electrons from a substrate proximate to a second (or bottom) insulating layer (sometimes called a tunnel oxide) to tunnel through the second insulating layer and to the floating gate, which is sometimes referred to as tunneling or Fowler-Nordheim tunneling. Conversely, the floating gate transistor may be erased by applying a high voltage to the substrate, which causes electrons from the floating gate transistor to tunnel through the second insulating layer and to the substrate. A lack of charge in the floating gate transistor, a presence of a charge in the floating gate transistor, and/or a level of the charge in the floating gate transistor indicates a data state stored by the memory cell or floating gate transistor.

More particularly, a non-volatile memory cell, such as a NAND cell, may be categorized as an SLC, an MLC, a TLC, or a QLC, among other examples. As shown by reference number 305, an SLC stores a single binary bit per memory cell, and thus may store either binary 1 or binary 0. In an SLC, the stored bit is sometimes referred to as the page data of the memory cell. When writing to an SLC, the cell may be charged to a threshold voltage (Vth) falling within the distribution of the curve labeled with page data “1” when the memory cell is to store binary 1 (or else may include no charge when the memory cell is to store binary 1), and may be charged to a threshold voltage falling within the distribution of the curve labeled with page data “0” when the memory cell is to store binary 0.

Unlike an SLC, which only stores a single bit, an MLC, a TLC, and a QLC may store multiple bits per memory cell. More particularly, as shown by reference number 310, an MLC stores two binary bits per memory cell, and thus is capable of storing binary 11, binary 01, binary 00, or binary 10 according to a level of a charge stored in the MLC. In an MLC, a first stored bit is sometimes referred to as the cell's upper page data, and the second stored bit is sometimes referred to as the cell's lower page data. When writing to an MLC, the cell may be charged to a threshold voltage falling within the distribution of the curve labeled with page data “11” when the memory cell is to store binary 11, the cell may be charged to a threshold voltage falling within the distribution of the curve labeled with page data “01” when the memory cell is to store binary a 01, the cell may be charged to a threshold voltage falling within the distribution of the curve labeled with page data “00” when the memory cell is to store binary 00, and the cell may be charged to a threshold voltage falling within the distribution of the curve labeled with page data “10” when the memory cell is to store binary 10. In some implementations, an MLC stores binary 11 when the MLC's charge is approximately 25% full, the MLC stores binary 01 when the MLC's charge is approximately 50% full, the MLC stores binary 00 when the MLC's charge is approximately 75%, and the MLC stores binary 10 when the MLC's charge is approximately 100% full.

In a similar manner, and as shown by reference number 315, a TLC stores three binary bits per memory cell, and thus a TLC is capable of storing binary 111, binary 011, binary 001, binary 101, binary 100, binary 000, binary 010, or binary 110. For a TLC, the first, second, and third stored bits are sometimes referred to as the cell's “extra page data,” the cell's “upper page data,” and the cell's “lower page data,” respectively. Moreover, as shown by reference number 320, a QLC stores four binary bits per memory cell, and thus is capable of storing binary 1111, binary 0111, binary 0011, binary 1011, binary 1001, binary 0001, binary 0101, binary 1101, binary 1100, binary 0100, binary 0000, binary 1000, binary 1010, binary 0010, binary 0110, or binary 1110. For a QLC, the first, second, third, and fourth bits are sometimes referred to as the cell's “top page data,” the cell's “extra page data,” the cell's “upper page data,” and the cell's “lower page data,” respectively. More broadly, for an n-bit memory cell, the threshold voltage of the cell may be programmed to 2n separate states, with each state corresponding to a non-overlapping threshold distribution, as shown for the various memory cells in FIG. 3.

To read the data stored in a memory cell, such as an SLC, an MLC, a TLC, a QLC, or another type of memory cell, a memory device (or a component thereof) may sense a voltage associated with the stored charge on the memory cell (e.g., may sense a Vth associated with the cell) and determine a corresponding binary number associated with that voltage.

In some examples, the memory device 120 may charge a cell over a programming time (e.g., a tProg). For example, the memory device 120 may charge the cell by incrementally increasing or decreasing a voltage of the charge over the programming time. By increasing the programming time, the increments by which the memory device 120 increases or decreases the voltage may be made smaller. This may enable the memory device 120 to more accurately charge the memory cell to a voltage level associated with a desired binary bit value. For example, using the smaller increments, the memory device 120 may be enabled to charge a memory cell to a voltage that is closer to a peak or center of a voltage distribution (e.g., one of the curves shown in FIG. 3) of the desired binary bit value.

In some cases, a voltage associated with the stored charge on the memory cell may fluctuate over time due to unpowered storage and/or temperature effects, as described elsewhere herein. Memory cells that are capable of storing more binary bits in each cell (such as MLCs, TLCs, and/or QLCs) may experience more errors caused by a fluctuation in the voltage associated with the stored charge on a given memory cell because differences between threshold voltages associated with different binary values may be smaller (e.g., as compared to cells that are capable of storing fewer binary bits in each memory cell). For example, QLCs may experience more errors caused by data retention effects (e.g., associated with periods of unpowered storage and/or temperature effects) than SLCs, MLCs, and/or TLCs.

As indicated above, FIG. 3 is provided as an example. Other examples may differ from what is described with regard to FIG. 3.

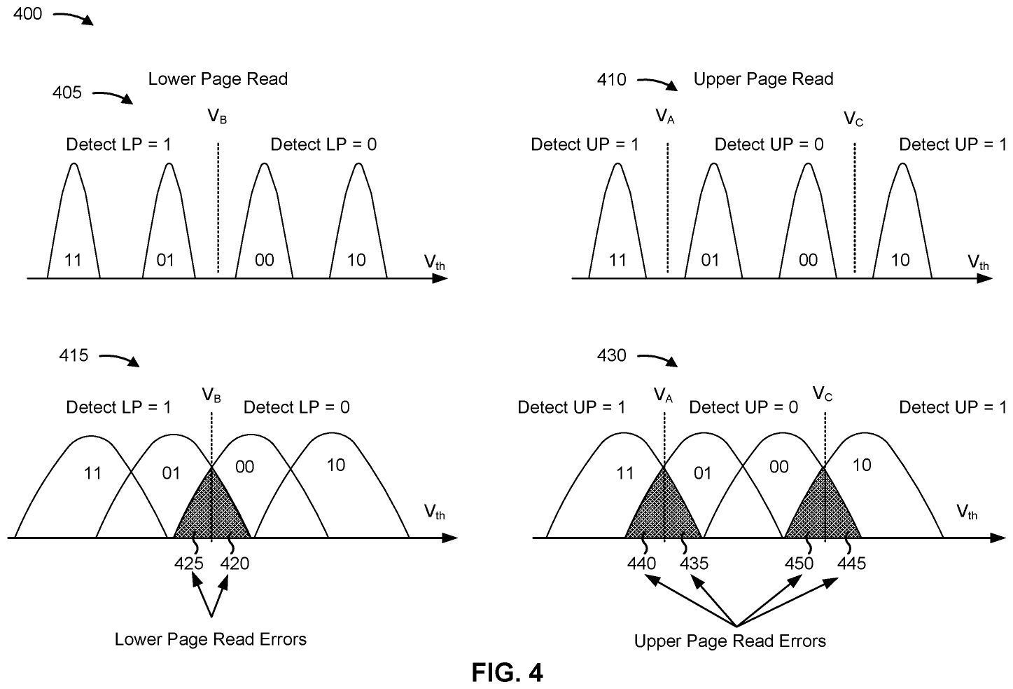

FIG. 4 is a diagram illustrating an example 400 of read errors that may occur in an MLC non-volatile memory device. Although the read errors described in connection with FIG. 4 are described in the context of an MLC, the described concepts also apply to other types of memory cells, such as SLCs, TLCs, QLCs, and other types of memory cells.

Some memory devices may be capable of storing multiple bits per memory cell. For example, an MLC non-volatile memory device (e.g., an MLC flash device) may be capable of storing two bits of information per memory cell in one of four states (e.g., may store binary 11, binary 01, binary 00, or binary 10 depending on a charge applied to the memory cell). To read the data of a memory cell, such as the MLC shown in FIG. 4, the memory device (or a component thereof) may apply a read reference voltage to the cell in an effort to induce current in the memory cell, and the memory device (or a component thereof) may determine a corresponding bit string associated with a voltage that induced (or else did not induce) current. Put another way, the memory device may apply various read reference voltages to sense the threshold voltage (Vth) associated with the data stored in the cell.

More particularly, for an MLC, the memory device may perform a lower page (also shown as LP) read and an upper page (also shown as UP) read. As shown by reference number 405, for a lower page read, the memory device may apply to a read reference voltage, shown as VB. VB may represent a voltage between threshold voltage distributions associated with the first two states (e.g., threshold voltage distributions associated with binary 11 and 01) and threshold voltage distributions associated with the second two states (e.g., threshold voltage distributions associated with binary 00 and 10). If current flows when VB is applied to the memory cell, then the threshold voltage may be considered to be less than VB, thus corresponding to one of binary 11 or binary 01 (meaning that the lower page data represents a “1”). If current does not flow when VB is applied to the memory cell, then the threshold voltage may be considered to be more than VB, thus corresponding to one of binary 00 or binary 10 (meaning that the lower page data represents a “0”).

As shown by reference number 410, an upper page read may be performed in a similar manner. More particularly, when the detected lower page data is a “1”, a read reference voltage of VA may be applied to the memory cell to thereafter determine the upper page data. VA may represent a voltage between a threshold voltage distribution associated with the first state (e.g., a threshold voltage distribution associated with binary 11) and a threshold voltage distribution associated with the second state (e.g., a threshold voltage distribution associated with binary 01). If current flows when VA is applied to the memory cell, then the threshold voltage may be considered to be less than VA, thus corresponding to binary 11 (meaning that the upper page data represents a “1”). If current does not flow when VA is applied to the memory cell, then the threshold voltage may be considered to be more than VA but less than VB (as determined during the lower page read), thus corresponding to binary 01 (meaning that the upper page data represents a “0”).

Similarly, when the detected lower page data is a “0,” a read reference voltage of VC may be applied to the memory cell to thereafter determine the upper page data. VC may represent a voltage between a threshold voltage distribution associated with the third state (e.g., a threshold voltage distribution associated with binary 00) and a threshold voltage distribution associated with the fourth state (e.g., a threshold voltage distribution associated with binary 10). If current flows when VC is applied to the memory cell, then the threshold voltage may be considered to be less than VC but more than VB (as determined during the lower page read), thus corresponding to binary 00 (meaning that the upper page data represents a “0”). If current does not flow when VC is applied to the memory cell, then the threshold voltage may be considered to be more than VC, thus corresponding to binary 10 (meaning that the upper page data represents a “1”).

In some cases, the threshold voltage distributions shown in FIG. 4 may be broadened due to noise or the like, which may lead to read errors at the memory device. Noise in the memory cell may be caused by various sources, such as program-erase (P/E) cycling stress, charge leakage over time, read disturbances (e.g., disturbances caused by the application of a high voltage to a memory cell of a page not being read to deselect the cell while other cells on the page are being read), programming errors, cell-to-cell interference (such as unintentional electrical disturbance and/or interference of a memory cell when neighboring cells are read, written, or erased), or the like. As shown in FIG. 4, broadened voltage threshold distributions may lead to read errors, such as lower page read errors and/or upper page read errors.

First, as shown by reference number 415, a lower page read error may be caused by the broadening of voltage distributions that are near VB and/or that overlap with VB. In the example shown in FIG. 4, the threshold voltage distributions associated with binary 01 and binary 00 have broadened to overlap with the read reference voltage VB. This may result in a lower page read error because a cell programmed with binary 01 may act in a similar manner to a cell programmed with binary 00 (e.g., in response to an applied voltage). More particularly, if VB is applied to a memory cell that stores binary 01 but that is associated with a threshold voltage in the area labeled with reference number 420, no current would flow, erroneously indicating that the lower page data represents a “0” rather than a “1”. On the other hand, if VB is applied to a memory cell that stores binary 00 but that is associated with a threshold voltage in the area labeled with reference number 425, current would flow, erroneously indicating that the lower page data represents a “1” rather than a “0”.

Similarly, as shown by reference number 430, when performing an upper page read, an upper page read error may be caused by the broadening of voltage distributions that are near VA and/or VC and/or that overlap with VA and/or VC. For example, memory cells storing binary 11 and associated with a threshold voltage in the area labeled by 435 may be erroneously read as storing upper page data of “0”, memory cells storing binary 01 and associated with a threshold voltage in the area labeled by 440 may be erroneously read as storing upper page data of “1”, memory cells storing binary 00 and associated with a threshold voltage in the area labeled by 445 may be erroneously read as storing upper page data of “1”, and memory cells storing binary 10 and associated with a threshold voltage in the area labeled by 450 may be erroneously read as storing upper page data of “0”.

In some cases, the memory device 120 may attempt to adjust one or more read reference voltages in response to one or more of the read errors described above (e.g., in response to a cell storing one logical value or binary number being misread as storing a different logical value or binary number). In some instances, this may be referred to as a read retry or a read recovery process. In a read recovery process, one or more read reference voltages (such as VA, VB, or VC described in connection with the MLC) may be dynamically adjusted to track changes in threshold voltage distributions. More particularly, once a read process fails on a particular page of a memory, the memory device 120 (and, more particularly, the controller 130 and/or the read recovery component 240 thereof) may attempt to recover the page using various read recovery steps, which use shifts in voltages from base read reference voltages. Put another way, the memory device 120 may retry the read of a cell with an adjusted read reference voltage such that read errors are decreased or eliminated.

Returning to the example shown in FIG. 4, if a lower page error resulted in a cell storing binary 00 being read as binary 01, the read reference voltage (VB) may be decreased (e.g., shifted to the left in the diagram shown by reference number 415) in an effort to eliminate the lower page read error. Conversely, if a lower page error resulted in a cell storing binary 01 being read as binary 00, the read reference voltage (VB) may be increased (e.g., shifted to the right in the diagram shown by reference number 415). Similarly, the read reference voltages VA and VC may be shifted left or right (e.g., decreased or increased) in an effort to reduce or eliminate upper page read errors. In some cases, if a quantity of errors for bits of data becomes too large, the memory device 120 may be unable to correct the errors. This may result in the data being lost.

As indicated above, FIG. 4 is provided as an example. Other examples may differ from what is described with regard to FIG. 4.

FIGS. 5A and 5B are diagrams of an example 500 of dynamic programming time for a memory device. The operations described in connection with FIGS. 5A and 5B may be performed by the memory device 120 and/or one or more components of the memory device 120, such as the controller 130 and/or one or more components of the controller 130.

In some implementations, the memory device 120 and/or the controller 130 may be configured with multiple programming times (e.g., multiple amounts of time that can be used for the programming time). For example, the memory device 120 and/or the controller 130 may store multiple programming times. Some examples are described herein associated with a first programming time (e.g., associated with a first amount of time) and a second programming time (e.g., associated with a second amount of time). However, the memory device 120 and/or the controller 130 may store and/or use more than two programming times in a similar manner as described herein.

In some implementations, the memory device 120 and/or the controller 130 may be configured with a default programming time. The default programming time may be a programming time to be used by the memory device 120 and/or the controller 130 until a trigger event (e.g., associated with switching the programming time) is detected, as described in more detail elsewhere herein. For example, the memory device 120 and/or the controller 130 may be configured to use the default programming time (e.g., a first programming time) unless a trigger event is detected by the memory device 120 and/or the controller 130.

In some implementations, the memory device 120 and/or the controller 130 may be configured to detect one or more trigger events. For example, a trigger event may include an event that causes the memory device 120 and/or the controller 130 to switch a programming time used to write or program data (e.g., to switch or change an amount of time associated with the programming time used to write or program data). For example, a trigger event may include receiving a command (e.g., a vendor command or a VS command) from the host device 110 indicating that the programming time is to be switched, a block erase count satisfying an erase count threshold, and/or a quantity of program-erase cycles satisfying a program-erase threshold, among other examples.

As shown in FIG. 5A, and by reference number 505, the host device 110 may transmit, and the memory device 120 and/or the controller 130 may receive, a write command. The write command may indicate one or more write operations to be performed by the memory device 120 and/or the controller 130. For example, the write command may indicate data to be written to or programmed in the memory 140.

As shown by reference number 510, the memory device 120 and/or the controller 130 may determine a programming time to use for writing the data indicated by the write command. For example, the memory device 120 and/or the controller 130 may determine an amount of time associated with the programming time. In some implementations, the memory device 120 and/or the controller 130 may determine the programming time based on whether a trigger event has been detected. For example, if a trigger event has been detected by the memory device 120 and/or the controller 130, then the memory device 120 and/or the controller 130 may determine that the programming time is a first programming time. If a trigger event has not been detected by the memory device 120 and/or the controller 130, then the memory device 120 and/or the controller 130 may determine that the programming time is a second programming time.

In some implementations, the memory device 120 and/or the controller 130 may store an indication of a current programming time. For example, the memory device 120 and/or the controller 130 may be configured to use a default (e.g., a first) programming time until a trigger event is detected. After a trigger event is detected, the memory device 120 and/or the controller 130 may change the amount of time associated with the programming time (e.g., may change the current programming time to a second programming time).

In some implementations, the memory device 120 and/or the controller 130 may determine the programming time based on an operation phase associated with the memory device 120. For example, a first programming time may be associated with a first operation phase (e.g., a manufacturing phase or an initialization phase) and a second programming time may be associated with a second operation phase (e.g., an end user phase). Therefore, the memory device 120 and/or the controller 130 may determine a current operation phase of the memory device 120. The memory device 120 and/or the controller 130 may determine the programming time based on the current operation phase.

In some implementations, the memory device 120 and/or the controller 130 may determine the programming time based on a data type associated with the data indicated by the write command. For example, the first programming time may be associated with a first data type (e.g., OEM data, ODM data, initialization data, or operating system (OS) data) and the second programming time may be associated with a second data type (e.g., user data). The memory device 120 and/or the controller 130 may determine the data type associated with the data indicated by the write command. The memory device 120 may determine or select the programming time based on the data type.

In some implementations, the memory device 120 and/or the controller 130 may determine the programming time based on a block erase count associated with a memory block (e.g., to be associated with the data indicated by the write command). For example, the memory device 120 and/or the controller 130 may determine a block erase count. The block erase count may be a total block erase count associated with the memory device 120 (e.g., indicating a quantity of blocks that have been erased) and/or may be a block erase count associated with a memory block to be written or programmed. The memory device 120 and/or the controller 130 may determine whether the block erase count satisfies a threshold (e.g., an erase count threshold). The memory device 120 and/or the controller 130 may determine the programming time based on whether the block erase count satisfies the threshold. For example, if the block erase count does not satisfy the threshold, then the memory device 120 and/or the controller 130 may determine that the programming time is the first programming time. If the block erase count satisfies the threshold, then the memory device 120 and/or the controller 130 may determine that the programming time is the second programming time.

Additionally, or alternatively, the memory device 120 and/or the controller 130 may determine the programming time based on a quantity of program-erase cycles. For example, the memory device 120 and/or the controller 130 may determine a quantity of program-erase cycles performed by the memory device 120 (e.g., for the entire memory device 120 and/or for a memory block to be written). The memory device 120 and/or the controller 130 may determine whether the quantity of program-erase cycles satisfies a threshold (e.g., a program-erase threshold). The memory device 120 and/or the controller 130 may determine the programming time based on whether the quantity of program-erase cycles satisfies the threshold. For example, if the quantity of program-erase cycles does not satisfy the threshold, then the memory device 120 and/or the controller 130 may determine that the programming time is the first programming time. If the quantity of program-erase cycles satisfies the threshold, then the memory device 120 and/or the controller 130 may determine that the programming time is the second programming time.

For example, data that needs to be maintained by the memory device 120 over longer periods of time (e.g., on unpowered storage) may be written and/or programmed by the memory device 120 early on in a lifespan of the memory device. For example, the data may be written or programmed in a factory before the memory device 120 and/or the host device 110 is shipped to a merchant and/or end user (e.g., where the shipment and storage after the factory setting is associated with long periods of unpowered storage and/or high temperature stresses). In such scenarios, the block erase count and/or quantity of program-erase cycles may be low. Therefore, the memory device 120 and/or the controller 130 may determine the programming time based on the block erase count and/or quantity of program-erase cycles to enable the memory device 120 and/or the controller 130 to use a first programming time (e.g., a longer programming time) to program the data in a factory setting and to use a second programming time (e.g., a shorter programming time) for end user operations. This may enable the memory device 120 and/or the controller 130 to dynamically switch the programming time without relying on host device commands or other input from outside the memory device 120.

As shown by reference number 515, the memory device 120 and/or the controller 130 may write or program data (e.g., to the memory 140) using the first programming time. For example, the memory device 120 and/or the controller 130 may perform one or more write operations using the first programming time. For example, the memory device 120 and/or the controller 130 may write or program data (e.g., to the memory 140) using the first programming time (e.g., a longer programming time) to improve the integrity of the data and/or to mitigate the effects of data retention degradation, as described in more detail elsewhere herein. For example, the data written or programmed using the first programming time (e.g., a longer programming time) may be associated with writing OEM data, ODM data, initialization data, and/or OS data, among other examples. For example, the data written or programmed using the first programming time (e.g., a longer programming time) may be associated with data written or programmed in a manufacturer and/or factory setting. In other words, the data written or programmed using the first programming time (e.g., a longer programming time) may be associated with a first operation phase (e.g., a manufacturing phase, an initialization phase, or a factory phase) of the memory device 120. The memory device 120 and/or the controller 130 may continue to write and/or program data using the first programming time until a trigger event is detected.

For example, as shown by reference number 520, the memory device 120 and/or the controller 130 may detect a trigger event associated with changing the programming time used by the memory device 120 and/or the controller 130. In some implementations, the memory device 120 and/or the controller 130 may detect the trigger event based on a command received from the host device 110. For example, the host device 110 may transmit, and the memory device 120 and/or the controller 130 may receive, a command indicating that the programming time is to be switched from the first programming time to the second programming time. The command may be a vendor command or a vendor specific command. For example, a command may be defined (e.g., in a command table stored by the memory device 120 and/or the controller 130) that is associated with causing the memory device 120 and/or the controller 130 to switch the programming time from the first programming time to the second programming time. The host device 110 may transmit the command to cause the memory device 110 and/or the controller 130 to switch the programming time to the second (e.g., shorter) programming time.

Additionally, or alternatively, the memory device 120 and/or the controller 130 may detect the trigger event based on a block erase count and/or a quantity of program-erase cycles associated with the memory device 120. For example, the memory device 120 and/or the controller 130 may detect that the block erase count satisfies a threshold (e.g., an erase count threshold). The memory device 120 and/or the controller 130 may switch the programming time to the second programming time based on detecting that the block erase count satisfies the erase count threshold. In some implementations, a value of the erase count threshold may be based on a data write size of data to be written using the first programming time. For example, the memory device 120 and/or the controller 130 may be configured to write or program manufacturer data, such as OEM or ODM data (e.g., an OS), using the first programming time. The value of the erase count threshold may be defined based on a size of the manufacturer data to be programmed, such that after the manufacturer data is programmed the memory device 120 and/or the controller 130 may be triggered to switch the programming time to the second (e.g., shorter) programming time for future write operations (e.g., for user data). In other words, the value of the erase count threshold can be designed according to a data write size from an ODM of the memory device 120 and/or the host device 110.

As shown in FIG. 5B, and by reference number 525, the memory device 120 and/or the controller 130 may switch, based on detecting the trigger event, the programming time from the first programming time to the second programming time (e.g., where the second programming time is associated with a second amount of time). In some implementations, the first amount of time (e.g., associated with the first programming time) may be greater than the second amount of time (e.g., associated with the second programming time). For example, after detecting the trigger event, the memory device 120 and/or the controller 130 may use a shorter programming time to improve the performance of the memory device 120 (e.g., to reduce an amount of time associated with write operations). For example, the memory device 120 and/or the controller 130 may change, based on detecting the trigger event, an amount of time associated with the programming time (e.g., from the first amount of time to the second amount of time).

As shown by reference number 530, the host device 110 may transmit, and the memory device 120 and/or the controller 130 may receive, a write command. The write command may indicate one or more write operations to be performed by the memory device 120 and/or the controller 130. For example, the write command may indicate data to be written to or programmed in the memory 140.

As shown by reference number 535, the memory device 120 and/or the controller 130 may determine a programming time to use for writing the data indicated by the write command. For example, the memory device 120 and/or the controller 130 may determine an amount of time associated with the programming time. In some implementations, the memory device 120 and/or the controller 130 may determine the programming time based on whether the trigger event has been detected. For example, if the memory device 120 and/or the controller 130 detect a trigger event, then the memory device 120 and/or the controller 130 may use the second programming time. In some implementations, the memory device 120 and/or the controller 130 may store an indication of the current programming time. After the trigger event is detected, the memory device 120 and/or the controller 130 may change the amount of time associated with the programming time (e.g., may change the current programming time to the second programming time), as described above.

In some implementations, the memory device 120 and/or the controller 130 may determine the programming time based on an operation phase associated with the memory device 120. For example, a first programming time may be associated with a first operation phase (e.g., a manufacturing phase or an initialization phase) and a second programming time may be associated with a second operation phase (e.g., an end user phase). Therefore, the memory device 120 and/or the controller 130 may determine a current operation phase of the memory device 120. The memory device 120 and/or the controller 130 may determine the programming time based on the current operation phase. For example, the memory device 120 and/or the controller 130 may determine that the current operation phase is an end user phase. An end user phase may be associated with use of the memory device 120 and/or the controller 130 by an end user. The memory device 120 and/or the controller 130 may determine that the programming time is the second programming time based on determining that the current operation phase is an end user phase. In some implementations, the memory device 120 and/or the controller 130 may determine the programming time based on a data type associated with the data indicated by the write command (e.g., if the data is user data, then the memory device 120 and/or the controller 130 may use the second programming time).

In some implementations, the memory device 120 and/or the controller 130 may determine the programming time based on a block erase count. For example, the memory device 120 and/or the controller 130 may determine a block erase count. The memory device 120 and/or the controller 130 may determine whether the block erase count satisfies a threshold (e.g., an erase count threshold). The memory device 120 and/or the controller 130 may determine the programming time based on whether the block erase count satisfies the threshold. If the block erase count satisfies the threshold, then the memory device 120 and/or the controller 130 may determine that the programming time is the second programming time. Additionally, or alternatively, the memory device 120 and/or the controller 130 may determine the programming time based on a quantity of program-erase cycles, as described in more detail elsewhere herein.

As shown by reference number 540, the memory device 120 and/or the controller 130 may write or program data (e.g., to the memory 140) using the second programming time. For example, the memory device 120 and/or the controller 130 may perform one or more write operations using the second programming time. For example, the memory device 120 and/or the controller 130 may write or program data (e.g., to the memory 140) using the second programming time (e.g., a shorter programming time) to improve the performance of the memory device 120 for an end user, as described in more detail elsewhere herein. For example, the data written or programmed using the second programming time (e.g., a shorter programming time) may be associated with writing user data, among other examples. For example, the data written or programmed using the second programming time (e.g., a shorter programming time) may be associated with an end user. In other words, the data written or programmed using the second programming time (e.g., a shorter programming time) may be associated with a second operation phase (e.g., an end user phase) of the memory device 120. The memory device 120 and/or the controller 130 may continue to write and/or program data using the second programming time until another trigger event is detected and/or may always use the second programming time after detecting the trigger event.

As a result, by dynamically changing the programming time used by the memory device 120 and/or the controller 130, the memory device 120 is enabled to improve data integrity and/or mitigate the effects of data retention degradation by writing data using a longer programming time in some cases while also improving the performance of the memory device 120 by writing data using a shorter programming time in other cases. For example, the memory device 120 is enabled to balance between improving data integrity and performance of the memory device 120 based on an operation phase and/or a type of data being stored by the memory device 120. This enables the memory device 120 to improve data integrity and/or mitigate the effects of data retention degradation (e.g., associated with periods of unpowered storage and/or transportation) without degrading the performance of the memory device 120 (e.g., for an end user).

As indicated above, FIGS. 5A and 5B is provided as an example. Other examples may differ from what is described with regard to FIGS. 5A and 5B.

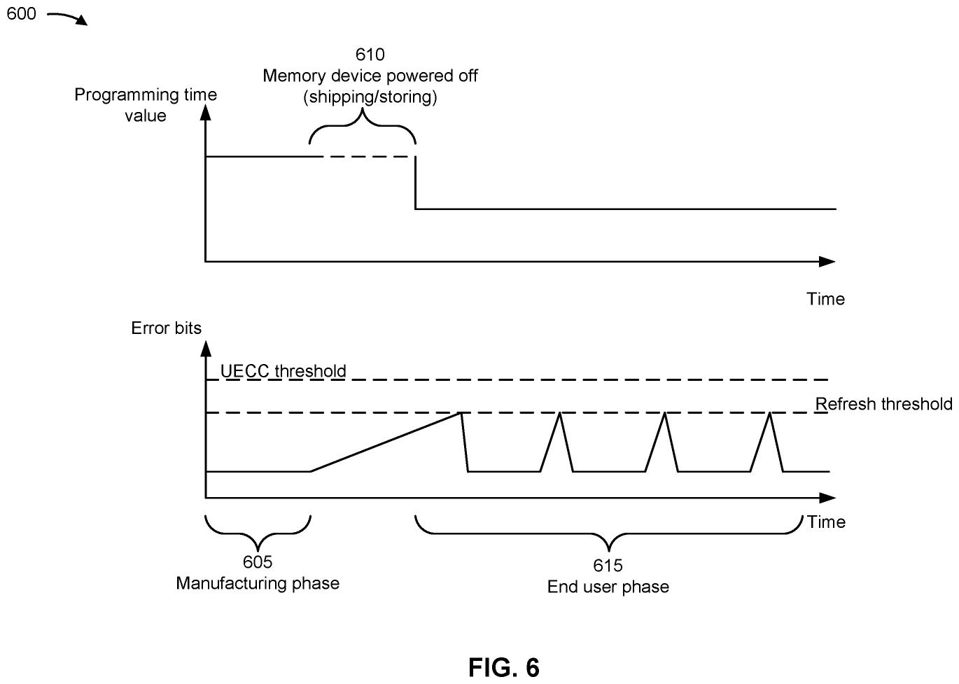

FIG. 6 is a diagram of an example 600 of a timeline associated with a dynamic programming time for a memory device. The operations described in connection with FIG. 6 may be performed by the memory device 120 and/or one or more components of the memory device 120, such as the controller 130 and/or one or more components of the controller 130.

As shown in FIG. 6, during a first operation phase (e.g., a manufacturing phase 605), the memory device 120 and/or the controller 130 may use a first programming time to write or program data. For example, during the manufacturing phase 605, ODM, OEM, and/or OS data may be written or programmed by the memory device 120 and/or the controller 130 (e.g., using the first programming time). For example, data written or programmed during the manufacturing phase 605 may be data that will be maintained by the memory device 120 during a period of powered off storage (e.g., as shown by reference number 610). For example, after the memory device 120 and/or the host device 110 leaves a vendor facility (e.g., a factory), the memory device 120 and/or the host device 110 may be shipped and/or stored in an unpowered state. Additionally, during shipping and/or storage, the memory device 120 may experience extreme temperature conditions. These conditions (e.g., prolonged unpowered storage and/or extreme temperature conditions) may cause the effects of data retention degradation to be amplified. Therefore, to mitigate the effects of the data retention degradation and to improve the integrity of the data written during the manufacturing phase 605, the first programming time may be a longer programming time. For example, as described elsewhere herein, a longer programming time may enable the memory device 120 and/or the controller 130 to charge a voltage level of a memory cell with improved accuracy, thereby reducing a likelihood of a read error associated with a bit stored by the memory cell.

As shown in FIG. 6, during the time that the memory device 120 is powered off, some bits of data may experience errors. However, because of the longer programming time used by the memory device 120 during the manufacturing phase 605, a rate at which bits experience errors may be reduced (e.g., as compared to if a shorter programming time were to be used to program the data). The memory device 120 and/or the host device 110 may be delivered to an end user and the memory device 120 may transition to an end user phase 615. For example, the memory device 120 and/or the host device 110 may be powered on after being shipped and/or stored in the unpowered state. After being powered on, the memory device 120 and/or the controller 130 may be enabled to perform read recovery operations for data written or programmed during the manufacturing phase 605. As shown in FIG. 6, because the rate at which bits experience errors may be reduced, a quantity of errors associated with bits may not reach a UECC threshold (e.g., the UECC threshold may indicate a quantity of error bits at which data can no longer be recovered by the memory device 120). In other words, by reducing the rate at which bits experience errors (e.g., by using a longer programming time), a likelihood that the memory device 120 is able to recover data bits that experience an error during the time that the memory device is powered off is improved.

As shown in FIG. 6, during the end user phase 615, the memory device 120 and/or the controller 130 may use a second programming time to write or program data. For example, the memory device 120 and/or the controller 130 may switch to a shorter programming time. The shorter programming time improves the performance of the memory device 120 because the amount of time associated with write operations is reduced. As shown in FIG. 6, using the shorter programming time may result in a rate at which bits experience errors to be increased (e.g., as compared to a rate for data programmed using the first (longer) programming time). However, because the memory device 120 is often or frequently powered on during the end user phase 615 (e.g., in contrast to the time shown by reference number 610), the memory device 120 and/or the controller 130 may be enabled to perform read recovery operations and/or refresh operations to ensure that data is not lost. For example, when a quantity of errors associated with data satisfies a refresh threshold, the memory device 120 and/or the controller 130 may read the data, correct errors in the data, and re-write the data to ensure that the data is not lost. As another example, the memory device 120 and/or the controller 130 may periodically, randomly, and/or on command (e.g., based on receiving a command from the host device 110) perform read operations for purposes of checking whether information stored in the memory 140 has errors (e.g., which may be referred to as a “patrol” read). Therefore, because the memory device 120 is powered on frequently during the end user phase 615, the memory device 120 may be enabled to correct errors that may result from using the shorter programming time.

As a result, the memory device 120 is enabled to cause data written during a first phase (e.g., the manufacturing phase 605) to have improved integrity over a longer period of time (e.g., by using a longer programming time) and to improve the performance of the memory device 120 during a second phase (e.g., the end user phase) by using a shorter programming time. The memory device 120 may switch between the first programming time and the second programming time based on detecting a trigger event, as described in more detail elsewhere herein.

As indicated above, FIG. 6 is provided as an example. Other examples may differ from what is described with regard to FIG. 6.

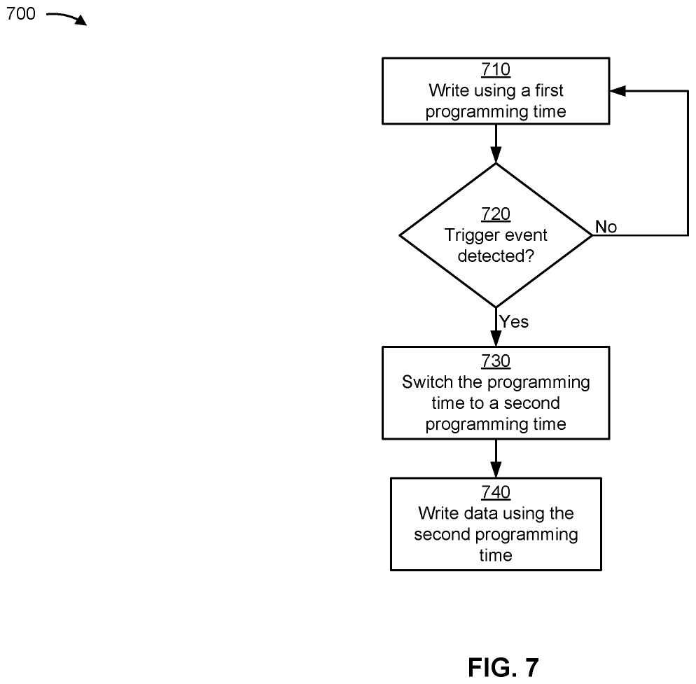

FIG. 7 is a diagram of an example 700 of a dynamic programming time for a memory device. The operations described in connection with FIG. 7 may be performed by the memory device 120 and/or one or more components of the memory device 120, such as the controller 130 and/or one or more components of the controller 130.

The memory device 120 and/or the controller 130 may write data (e.g., associated with the write operation) using a first programming time (block 710). For example, the memory device 120 and/or the controller 130 may be configured to use the first programming time for writing or programming data. For example, the memory device 120 and/or the controller 130 may receive one or more write commands from the host device 110.

The memory device 120 and/or the controller 130 may determine whether a trigger event has been detected (block 720). As described in more detail elsewhere herein, a trigger event may include receiving a command (e.g., a vendor specific command) from the host device 110, a block erase count satisfying an erase count threshold, and/or a quantity of program-erase cycles satisfying a program-erase threshold, among other examples. If the memory device 120 and/or the controller 130 determines that a trigger event has not been detected (block 720—No), then the memory device 120 and/or the controller 130 may continue to write or program data using the first programming time.

If the memory device 120 and/or the controller 130 determines that a trigger event has been detected (block 720—Yes), then the memory device 120 and/or the controller 130 may switch the programming to a second programming time (block 730). For example, the memory device 120 and/or the controller 130 may change, based on detecting the trigger event, an amount of time used to program data to a memory cell from the first programming time to the second programming time. In some implementations, the first programming time may be associated with a greater amount of time than an amount of time associated with the second programming time. In other words, based on detecting the trigger event, the memory device 120 and/or the controller 130 may reduce the programming time used by the memory device 120 and/or the controller 130. For example, if a trigger event has not been detected by the memory device 120 and/or the controller 130, then the memory device 120 and/or the controller 130 may select the first programming time for writing data. If a trigger event has been detected by the memory device 120 and/or the controller 130, then the memory device 120 and/or the controller 130 may select the second programming time for writing the data.

The memory device 120 and/or the controller 130 may write data using the second programming time (block 740). For example, the memory device 120 and/or the controller 130 may be configured to use the second programming time for write operations after detecting the trigger event.

As indicated above, FIG. 7 is provided as an example. Other examples may differ from what is described with regard to FIG. 7.

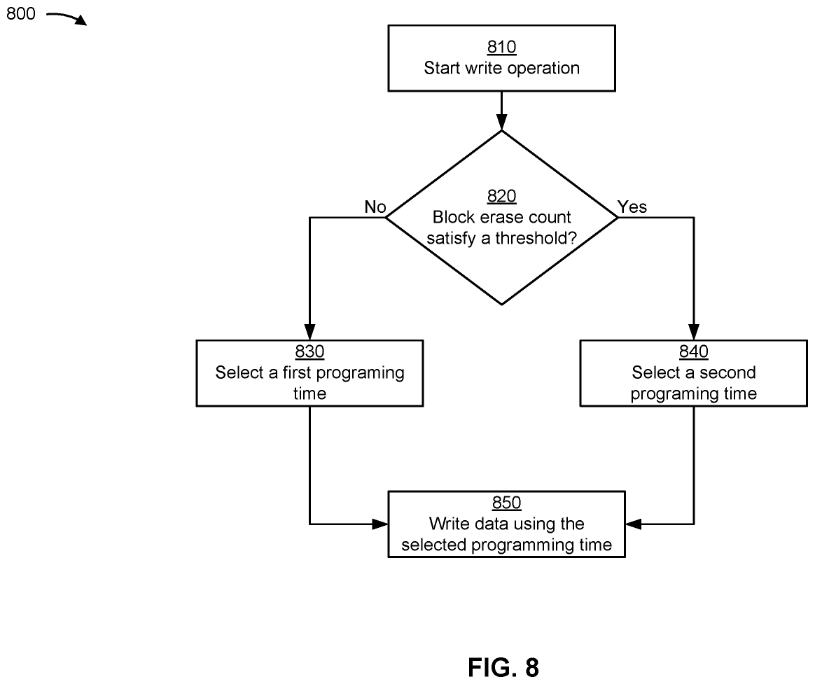

FIG. 8 is a diagram of an example 800 of dynamic programming time for a memory device. The operations described in connection with FIG. 8 may be performed by the memory device 120 and/or one or more components of the memory device 120, such as the controller 130 and/or one or more components of the controller 130.

The memory device 120 and/or the controller 130 may start a write operation (block 810). For example, the memory device 120 and/or the controller 130 may receive a write command from the host device 110. The memory device 120 and/or the controller 130 may determine whether a block erase count satisfies a threshold (block 820). The block erase count may be a quantity of blocks that have been erased by the memory device 120. In some implementations, a value of the threshold may be based on a size of data that is to be written or programmed using a first programming time. For example, the value of the threshold may be based on an expected quantity of program-erase cycles to be associated with data that is to be written or programmed using a first programming time.

If the memory device 120 and/or the controller 130 determines that the block erase count does not satisfy the threshold (block 820—No), then the memory device 120 and/or the controller 130 may select the first programming time for writing or programming the data indicated by the write command (block 830). If the memory device 120 and/or the controller 130 determines that the block erase count satisfies the threshold (block 820—Yes), then the memory device 120 and/or the controller 130 may select a second programming time for writing or programming the data indicated by the write command (block 840).

The memory device 120 and/or the controller 130 may write or program the data using the selected programming time (block 850). For example, if the block erase count does not satisfy the threshold, then the memory device 120 and/or the controller 130 may write or program the data using the first programming time. If the block erase count satisfies the threshold, then the memory device 120 and/or the controller 130 may write or program the data using the second programming time.

As indicated above, FIG. 8 is provided as an example. Other examples may differ from what is described with regard to FIG. 8.

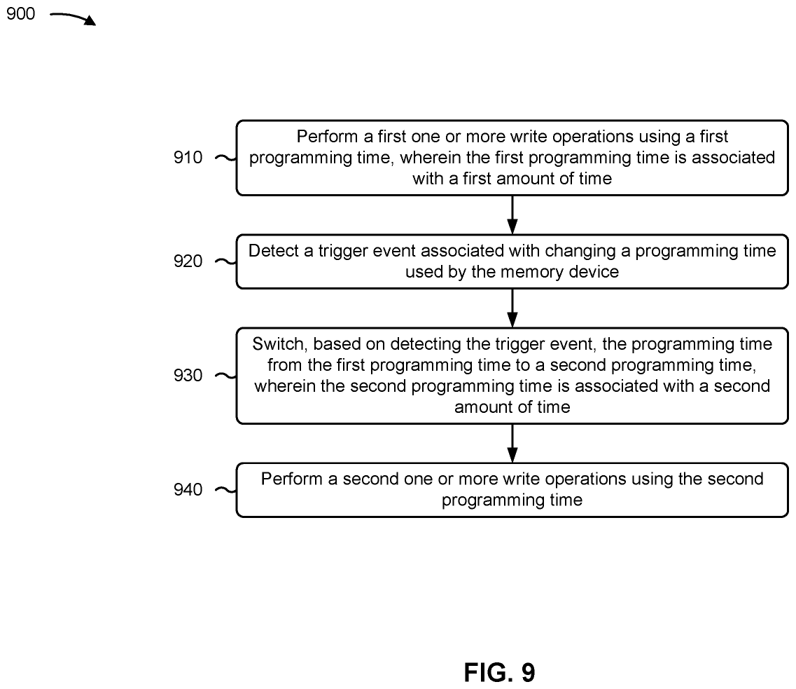

FIG. 9 is a flowchart of an example method 900 associated with a dynamic programming time for a memory device. In some implementations, a memory device (e.g., the memory device 120) may perform or may be configured to perform the method 900. In some implementations, another device or a group of devices separate from or including the memory device (e.g., the system 100) may perform or may be configured to perform the method 900. Additionally, or alternatively, one or more components of the memory device (e.g., the controller 130, the memory management component 225, the programming time management component 230, the event detection component 235, and/or the read recovery component 240) may perform or may be configured to perform the method 900. Thus, means for performing the method 900 may include the memory device and/or one or more components of the memory device. Additionally, or alternatively, a non-transitory computer-readable medium may store one or more instructions that, when executed by the memory device (e.g., the controller 130 of the memory device 120), cause the memory device to perform the method 900.

As shown in FIG. 9, the method 900 may include performing first one or more write operations using a first programming time, wherein the first programming time is associated with a first amount of time (block 910). As further shown in FIG. 9, the method 900 may include detecting a trigger event associated with changing a programming time used by the memory device (block 920). As further shown in FIG. 9, the method 900 may include switching, based on detecting the trigger event, the programming time from the first programming time to a second programming time, wherein the second programming time is associated with a second amount of time (block 930). As further shown in FIG. 9, the method 900 may include performing second one or more write operations using the second programming time (block 940).

The method 900 may include additional aspects, such as any single aspect or any combination of aspects described below and/or described in connection with one or more other methods or operations described elsewhere herein.

In a first aspect, the programming time used by the memory device indicates an amount of time associated with the memory device performing a write operation.

In a second aspect, alone or in combination with the first aspect, the first one or more write operations are associated with a first operation phase of the memory device and the second one or more write operations are associated with a second operation phase of the memory device.

In a third aspect, alone or in combination with one or more of the first and second aspects, the first one or more write operations are associated with writing original equipment manufacturer data or original design manufacturer data, and the second one or more write operations are associated with writing user data.

In a fourth aspect, alone or in combination with one or more of the first through third aspects, the first amount of time is greater than the second amount of time.

In a fifth aspect, alone or in combination with one or more of the first through fourth aspects, the method 900 includes receiving, from a host device, a command indicating that the programming time is to be switched from the first programming time to the second programming time.

In a sixth aspect, alone or in combination with one or more of the first through fifth aspects, the command is a vendor specific command.

In a seventh aspect, alone or in combination with one or more of the first through sixth aspects, the method 900 includes detecting that a block erase count, associated with a memory block to be written, satisfies a threshold.

In an eighth aspect, alone or in combination with one or more of the first through seventh aspects, a value of the threshold is based on a data write size of data associated with the first one or more write operations.

Although FIG. 9 shows example blocks of a method 900, in some implementations, the method 900 may include additional blocks, fewer blocks, different blocks, or differently arranged blocks than those depicted in FIG. 9. Additionally, or alternatively, two or more of the blocks of the method 900 may be performed in parallel. The method 900 is an example of one method that may be performed by one or more devices described herein. These one or more devices may perform or may be configured to perform one or more other methods based on operations described herein.

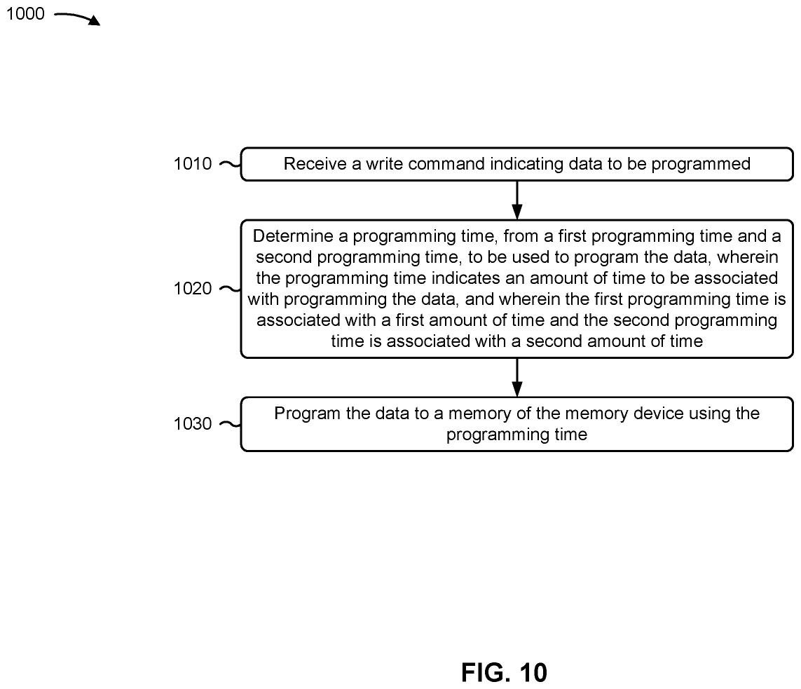

FIG. 10 is a flowchart of an example method 1000 associated with a dynamic programming time for a memory device. In some implementations, a memory device (e.g., the memory device 120) may perform or may be configured to perform the method 1000. In some implementations, another device or a group of devices separate from or including the memory device (e.g., the system 100) may perform or may be configured to perform the method 1000. Additionally, or alternatively, one or more components of the memory device (e.g., the controller 130, the memory management component 225, the programming time management component 230, the event detection component 235, and/or the read recovery component 240) may perform or may be configured to perform the method 1000. Thus, means for performing the method 1000 may include the memory device and/or one or more components of the memory device. Additionally, or alternatively, a non-transitory computer-readable medium may store one or more instructions that, when executed by the memory device (e.g., the controller 130 of the memory device 120), cause the memory device to perform the method 1000.

As shown in FIG. 10, the method 1000 may include receiving a write command indicating data to be programmed (block 1010). As further shown in FIG. 10, the method 1000 may include determining a programming time, from a first programming time and a second programming time, to be used to program the data, wherein the programming time indicates an amount of time to be associated with programming the data, and wherein the first programming time is associated with a first amount of time and the second programming time is associated with a second amount of time (block 1020). As further shown in FIG. 10, the method 1000 may include programming the data to a memory of the memory device using the programming time (block 1030).

The method 1000 may include additional aspects, such as any single aspect or any combination of aspects described below and/or described in connection with one or more other methods or operations described elsewhere herein.

In a first aspect, determining the programming time is based on a data type associated with the data, wherein the data type includes at least one of manufacturer data, or user data.

In a second aspect, alone or in combination with the first aspect, the first programming time is a default programming time, and the method 1000 includes receiving, from a host device, a command indicating that the programming time is to be switched from the first programming time to the second programming time.

In a third aspect, alone or in combination with one or more of the first and second aspects, determining the programming time comprises determining that the programming time is the second programming time based on receiving the command.

In a fourth aspect, alone or in combination with one or more of the first through third aspects, determining the programming time comprises determining a block erase count, determining whether the block erase count satisfies a threshold, and determining the programming time based on whether the block erase count satisfies the threshold.

In a fifth aspect, alone or in combination with one or more of the first through fourth aspects, determining the programming time comprises determining that the programming time is the first programming time if the block erase count does not satisfy the threshold, or the second programming time if the block erase count satisfies the threshold.

In a sixth aspect, alone or in combination with one or more of the first through fifth aspects, determining the programming time comprises determining an operation phase associated with the memory device, wherein the operation phase includes a manufacturing phase or an end user phase, and determining the programming time based on the operation phase associated with the memory device.

Although FIG. 10 shows example blocks of a method 1000, in some implementations, the method 1000 may include additional blocks, fewer blocks, different blocks, or differently arranged blocks than those depicted in FIG. 10. Additionally, or alternatively, two or more of the blocks of the method 1000 may be performed in parallel. The method 1000 is an example of one method that may be performed by one or more devices described herein. These one or more devices may perform or may be configured to perform one or more other methods based on operations described herein.

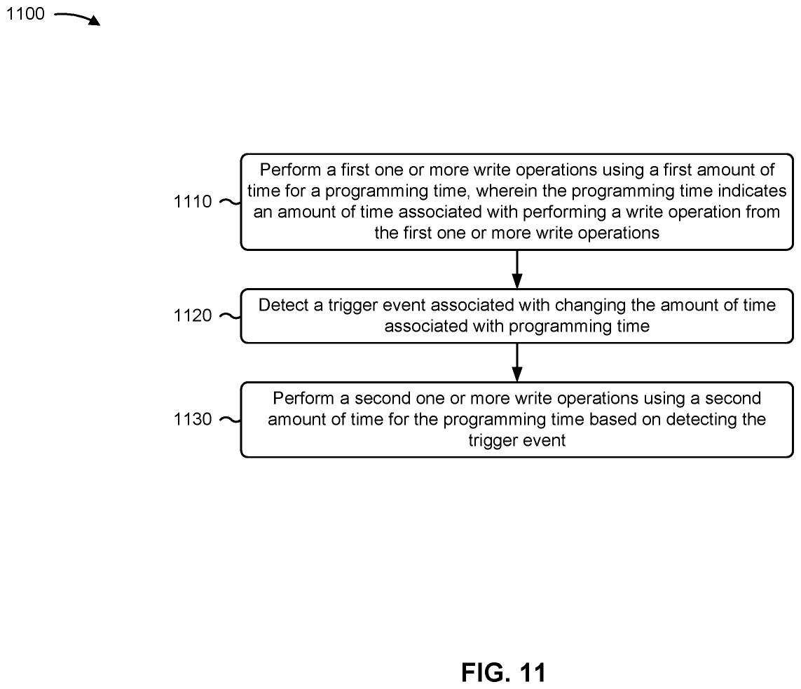

FIG. 11 is a flowchart of an example method 1100 associated with a dynamic programming time for a memory device. In some implementations, a memory device (e.g., the memory device 120) may perform or may be configured to perform the method 1100. In some implementations, another device or a group of devices separate from or including the memory device (e.g., the system 100) may perform or may be configured to perform the method 1100. Additionally, or alternatively, one or more components of the memory device (e.g., the controller 130, the memory management component 225, the programming time management component 230, the event detection component 235, and/or the read recovery component 240) may perform or may be configured to perform the method 1100. Thus, means for performing the method 1100 may include the memory device and/or one or more components of the memory device. Additionally, or alternatively, a non-transitory computer-readable medium may store one or more instructions that, when executed by the memory device (e.g., the controller 130 of the memory device 120), cause the memory device to perform the method 1100.

As shown in FIG. 11, the method 1100 may include performing a first one or more write operations using a first amount of time for a programming time, wherein the programming time indicates an amount of time associated with performing a write operation from the first one or more write operations (block 1110). As further shown in FIG. 11, the method 1100 may include detecting a trigger event associated with changing the amount of time associated with the programming time (block 1120). As further shown in FIG. 11, the method 1100 may include performing a second one or more write operations using a second amount of time for the programming time based on detecting the trigger event (block 1130).

The method 1100 may include additional aspects, such as any single aspect or any combination of aspects described below and/or described in connection with one or more other methods or operations described elsewhere herein.

In a first aspect, the first one or more write operations are associated with initialization data, the second one or more write operations are associated with user data, and the first amount of time is greater than the second amount of time.

In a second aspect, alone or in combination with the first aspect, the detecting the trigger event includes receiving, from a host device, a command indicating that the programming time is to be switched from the first amount of time to the second amount of time.

In a third aspect, alone or in combination with one or more of the first and second aspects, detecting the trigger event includes detecting that a block erase count satisfies a threshold.

Although FIG. 11 shows example blocks of a method 1100, in some implementations, the method 1100 may include additional blocks, fewer blocks, different blocks, or differently arranged blocks than those depicted in FIG. 11. Additionally, or alternatively, two or more of the blocks of the method 1100 may be performed in parallel. The method 1100 is an example of one method that may be performed by one or more devices described herein. These one or more devices may perform or may be configured to perform one or more other methods based on operations described herein.

In some implementations, a memory device includes one or more components configured to: perform first one or more write operations using a first programming time, wherein the first programming time is associated with a first amount of time; detect a trigger event associated with changing a programming time used by the memory device; switch, based on detecting the trigger event, the programming time from the first programming time to a second programming time, wherein the second programming time is associated with a second amount of time; and perform second one or more write operations using the second programming time.

In some implementations, a method includes receiving, by a memory device, a write command indicating data to be programmed; determining, by the memory device, a programming time, from a first programming time and a second programming time, to be used to program the data, wherein the programming time indicates an amount of time to be associated with programming the data, and wherein the first programming time is associated with a first amount of time and the second programming time is associated with a second amount of time; and programming, by the memory device, the data to a memory of the memory device using the programming time.

In some implementations, an apparatus includes means for performing a first one or more write operations using a first amount of time for a programming time, wherein the programming time indicates an amount of time associated with performing a write operation from the first one or more write operations; means for detecting a trigger event associated with changing the amount of time associated with the programming time; and means for performing a second one or more write operations using a second amount of time for the programming time based on detecting the trigger event.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising:
one or more components configured to:
perform first one or more write operations using a first programming time,
wherein the first programming time is associated with a first amount of time;
detect a trigger event associated with changing a programming time used by the memory device;
switch, based on detecting the trigger event, the programming time from the first programming time to a second programming time,
wherein the second programming time is associated with a second amount of time; and
perform second one or more write operations using the second programming time.

2. The memory device of claim 1, wherein the programming time used by the memory device indicates an amount of time associated with the memory device performing a write operation.

3. The memory device of claim 1, wherein the first one or more write operations are associated with a first operation phase of the memory device and the second one or more write operations are associated with a second operation phase of the memory device.

4. The memory device of claim 1, wherein the first one or more write operations are associated with writing original equipment manufacturer data or original design manufacturer data, and
wherein the second one or more write operations are associated with writing user data.

5. The memory device of claim 4, wherein the first amount of time is greater than the second amount of time.

6. The memory device of claim 1, wherein the one or more components, to detect the trigger event, are configured to:
receive, from a host device, a command indicating that the programming time is to be switched from the first programming time to the second programming time.

7. The memory device of claim 6, wherein the command is a vendor specific command.

8. The memory device of claim 1, wherein the one or more components, to detect the trigger event, are configured to:
detect that a block erase count, associated with a memory block to be written, satisfies a threshold.

9. The memory device of claim 8, wherein a value of the threshold is based on a data write size of data associated with the first one or more write operations.

10. A method, comprising:
receiving, by a memory device, a write command indicating data to be programmed;
determining, by the memory device, a programming time, from a first programming time and a second programming time, to be used to program the data,
wherein the programming time indicates an amount of time to be associated with programming the data, and
wherein the first programming time is associated with a first amount of time and the second programming time is associated with a second amount of time; and
programming, by the memory device, the data to a memory of the memory device using the programming time.

11. The method of claim 10, wherein determining the programming time is based on a data type associated with the data,
wherein the data type includes at least one of:
manufacturer data, or
user data.

12. The method of claim 10, wherein the first programming time is a default programming time, and the method further comprises:
receiving, from a host device, a command indicating that the programming time is to be switched from the first programming time to the second programming time.

13. The method of claim 12, wherein determining the programming time comprises:
determining that the programming time is the second programming time based on receiving the command.

14. The method of claim 10, wherein determining the programming time comprises:
determining a block erase count;
determining whether the block erase count satisfies a threshold; and
determining the programming time based on whether the block erase count satisfies the threshold.

15. The method of claim 14, wherein determining the programming time comprises:
determining that the programming time is:
the first programming time if the block erase count does not satisfy the threshold, or
the second programming time if the block erase count satisfies the threshold.

16. The method of claim 10, wherein determining the programming time comprises:
determining an operation phase associated with the memory device,
wherein the operation phase includes a manufacturing phase or an end user phase; and
determining the programming time based on the operation phase associated with the memory device.

17. An apparatus, comprising:
means for performing a first one or more write operations using a first amount of time for a programming time,
wherein the programming time indicates an amount of time associated with performing a write operation from the first one or more write operations;
means for detecting a trigger event associated with changing the amount of time associated with the programming time; and
means for performing a second one or more write operations using a second amount of time for the programming time based on detecting the trigger event.

18. The apparatus of claim 17, wherein the first one or more write operations are associated with initialization data,
wherein the second one or more write operations are associated with user data, and
wherein the first amount of time is greater than the second amount of time.

19. The apparatus of claim 17, wherein the means for detecting the trigger event comprises:
means for receiving, from a host device, a command indicating that the programming time is to be switched from the first amount of time to the second amount of time.

20. The apparatus of claim 17, wherein the means for detecting the trigger event comprises:
means for detecting that a block erase count satisfies a threshold.
